(19) United States
(12) Patent Application Publication
(10) Pub. No.: US 2025/0212374 A1
(43) Pub. Date: Jun. 26, 2025

(54) POWER SUPPLY DEVICE

(71) Applicant: TDK CORPORATION, Tokyo (JP)

(72) Inventors: Haruhiko IKEDA, Tokyo (JP); Genichiro Ishigooka, Tokyo (JP)

(73) Assignee: TDK CORPORATION, Tokyo (JP)

(21) Appl. No.: 18/965,158

(22) Filed: Dec. 2, 2024

(30) Foreign Application Priority Data
Dec. 22, 2023 (JP) 2023-216420

(51) Int. Cl. H05K 7/20

(52) U.S. Cl. CPC H05K 7/20909

(57) ABSTRACT

A power supply device that can effectively cool a plurality of coils using an air blower when such coils are arranged, for example, adjacent to each other is provided. The power supply device includes a first coil, a second coil, a substrate, an air blower, and a housing that houses the first coil, the second coil, the substrate, and the air blower. The first coil and the second coil are connected in series or in parallel. At least parts of the first coil and the second coil are included in a field of view at a viewpoint at which the first coil and the second coil are seen in the same direction as an air blowing direction of the air blower.

### CROSS-REFERENCE TO RELATED APPLICATION

Priority is claimed on Japanese Patent Application No. 2023-216420, filed Dec. 22, 2023, the content of which is incorporated herein by reference.

### BACKGROUND OF THE INVENTION

### Field of the Invention

The present disclosure relates to a power supply device

### Description of Related Art

In a power supply device, it is important to cool coils which are heat emitting parts.

For example, in a DC-DC converter described in Patent Document 1, two coils are successively arranged on a substrate (see FIG. 2 of Patent Document 1).

### Patent Documents

[Patent Document 1] Japanese Unexamined Patent Application, First Publication No. 2000-14149

### SUMMARY OF THE INVENTION

Here, for example, a configuration for cooling a coil using a fan is used in the power supply device.

However, in this related art, since two coils are successively arranged, for example, it is considered in the configuration using a fan that there may be a coil which wind from the fan does not directly reach, the coil is not sufficiently cooled, and a winding temperature of the coil increases. Particularly, in a configuration including a large number of parts or a configuration using a layout of parts with a high density, the temperatures of the parts are likely to increase and the winding temperatures of the coils are likely to increase.

The present disclosure was invented in consideration of the aforementioned circumferences, and an objective thereof is to provide a power supply device that can effectively cool a plurality of coils using an air blower when such coils are arranged, for example, adjacent to each other.

According to an aspect, there is provided a power supply device including a first coil, a second coil, a substrate, an air blower, and a housing that houses the first coil, the second coil, the substrate, and the air blower, wherein the first coil and the second coil are connected in series or in parallel, and at least parts of the first coil and the second coil are included in a field of view at a viewpoint at which the first coil and the second coil are seen in the same direction as an air blowing direction of the air blower.

With the power supply device according to the present disclosure, it is possible to effectively cool a plurality of coils using an air blower when such coils are arranged, for example, adjacent to each other.

### BRIEF DESCRIPTION OF THE DRAWINGS

FIG. 1 is a diagram schematically illustrating an example of a configuration of a power supply device according to an embodiment.

FIG. 2 is a diagram illustrating an example of a positional relationship among two coils, a pedestal, and a substrate according to a first embodiment.

FIG. 3 is a diagram illustrating an example of a positional relationship among two coils and a wind direction of a fan according to the first embodiment.

FIG. 4 is a diagram illustrating an example of a positional relationship between two coils when seen at a viewpoint based on a wind direction of a fan according to the first embodiment.

FIG. 5 is a diagram illustrating an example of a positional relationship between two coils when seen at a viewpoint based on a wind direction of a fan according to a modified example of the first embodiment.

FIG. 6 is a diagram illustrating an example of a positional relationship among two coils, a pedestal, and a substrate according to a second embodiment.

FIG. 7 is a diagram illustrating an example of a positional relationship between two coils and a wind direction of a fan according to the second embodiment.

FIG. 8 is a diagram illustrating an example of a positional relationship among two coils, a pedestal, and a substrate according to a third embodiment.

FIG. 9 is a diagram illustrating another example of a positional relationship between two coils.

FIG. 10 is a diagram illustrating another example of sizes of two coils.

FIG. 11 is a diagram illustrating an example of a positional relationship among three coils.

FIG. 12 is a diagram illustrating another example of the configuration of the fan.

### DETAILED DESCRIPTION OF THE INVENTION

Hereinafter, embodiments of the present disclosure will be described with reference to the accompanying drawings.

In the following description, a power supply device according to the embodiments will be described.

The power supply device may be referred to as, for example, a power converter device.

The power supply device may be a switching power supply device which is a specific example.

### First Embodiment

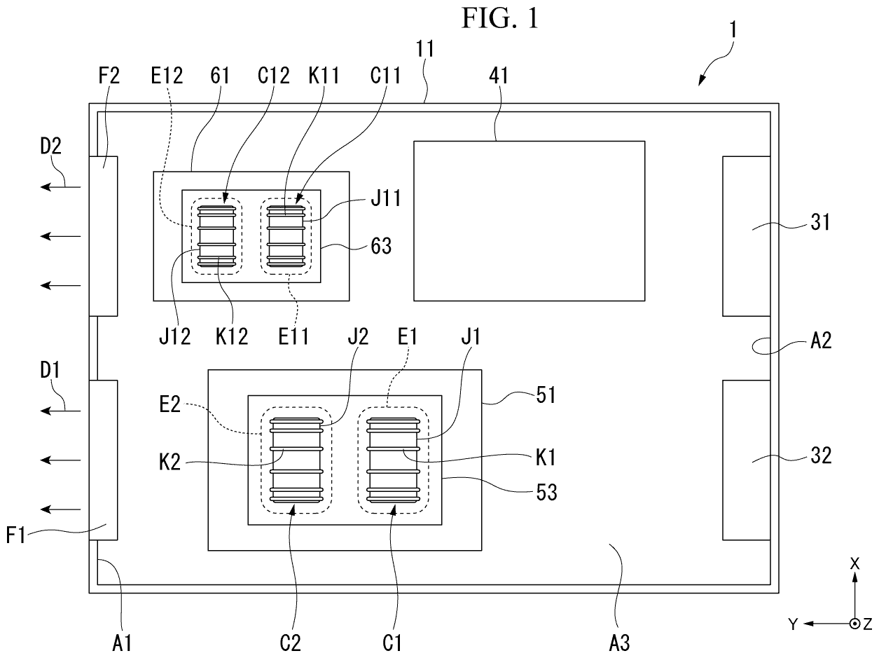

A first embodiment will be described with reference to FIGS. 1 to 5.

### [Power Supply Device]

FIG. 1 is a diagram schematically illustrating an example of a configuration of a power supply device 1 according to an embodiment.

In FIG. 1, XYZ orthogonal coordinate axes of a three-dimensional orthogonal coordinate system are illustrated for the purpose of convenience of explanation. In this embodiment, for the purpose of convenience of explanation, it is assumed that a direction from a positive side to a negative side of a Z axis is the gravitational direction. In this case, the positive side of the Z axis is up, the negative side of the Z axis is down, and an XY plane is a plane perpendicular to the gravitational direction.

The power supply device 1 includes a housing 11.

In this embodiment, the housing 11 has a cubic shape including six faces.

These six faces include a lower surface (bottom surface) parallel to the XY plane, an upper surface (top surface) parallel to the XY plane, a surface (one side surface) which is parallel to the XZ plane and which is located on the positive side of the Y axis, a surface (one side surface) which is parallel to the XZ plane and which is located on the negative side of the Y axis, a surface (one side surface) which is parallel to the YZ plane and which is located on the positive side of the X axis, and a surface (one side surface) 10 which is parallel to the YZ plane and which is located on the negative side of the X axis,

In the example illustrated in FIG. 1, the upper surface (the top surface) parallel to the XY plane is not illustrated (that is, is made to be transparent) in order to illustrate a configuration example in the housing 11.

In the example illustrated in FIG. 1, a configuration example in the housing 11 at a viewpoint at which the housing is seen from above to below is illustrated. In the example illustrated in FIG. 1, for the purpose of convenience of explanation, a surface which is parallel to the XZ plane and which is located on the positive side of the Y axis is defined as a surface A1, a surface which is parallel to the XZ plane and which is located on the negative side of the Y axis is defined as a surface A2, and the lower surface (the bottom surface) which is parallel to the XY plane is defined as a surface A3.

The housing 11 may include, for example, two or more parts (for example, a lid and a body), and these parts may be attachable and detachable.

The power supply device 1 includes an input terminal 31, an output terminal 32, a fan F1, a fan F2, a transformer 41, a substrate 51, a pedestal 53, a coil C1, a coil C2, a substrate 61, a pedestal 63, a coil C11, and a coil C12 as internal parts of the housing 11. Some of these parts may be provided outside of the housing 11. In a specific example, a part of the input terminal 31, a part of the output terminal 32, a part of the fan F1, and a part of the fan F2 may be exposed to the outside of the housing 11.

Here, the internal configuration of the housing 11 of the power supply device 1 illustrated in the example of FIG. 1 is an example for description and there is no limitation to this example.

The substrate 51 is a wiring board. The substrate 51 has a panel shape, and a planar surface thereof is disposed parallel (or almost parallel) to the bottom surface (the surface A3) of the housing 11.

The pedestal 53 includes a mounting part E1 and a mounting part E2. The coil C1 is mounted on the mounting part E1, and the coil C2 is mounted on the mounting part E2.

The coil Cl includes a core J1 and a winding K1. The winding K1 is wound on the toroidal core J1.

The coil C2 includes a core J2 and a winding K2. The winding K2 is wound on the toroidal core J2.

In this embodiment, the coil C1 and the coil C2 have the same shape.

In this embodiment, toroidal coils are used as the coils (the coil C1 and the coil C2 in this embodiment). In the toroidal coils, a wire of a conductor (the winding K1 and the winding K2 in this embodiment) is wound on a toroidal magnetic core (the core J1 or the core J2 in this embodiment).

The substrate 61 is a wiring board. The substrate 61 has a panel shape, and a planar surface thereof is disposed parallel (or almost parallel) to the bottom surface (the surface A3) of the housing 11.

The pedestal 63 includes a mounting part E11 and a mounting part E12. The coil C11 is mounted on the mounting part E11, and the coil C12 is mounted on the mounting part E12.

The coil C11 includes a core J11 and a winding K11. The winding K11 is wound on the toroidal core J11.

The coil C12 includes a core J12 and a winding K12. The winding K12 is wound on the toroidal core J12.

In this embodiment, the coil C11 and the coil C12 have the same shape.

The fan F1 and the fan F2 are provided on the surface A1 side of the housing 11.

In this embodiment, the fan F1 and the fan F2 are provided at positions which are symmetric with respect to the center of the surface A1 in a direction parallel to the X axis, but may be provided at different positions.

In this embodiment, the fan F1 and the fan F2 suck air into the housing 11, sends the air out on the surface A1 side, whereby a wind (an air flow) is generated in the housing 11.

In FIG. 1, for the purpose of convenience of explanation, a direction D1 of a wind which is formed by the fan F1 and a direction D2 of a wind which is formed by the fan F2 are illustrated. In this embodiment, the directions of the wind (the direction D1 and the direction D2) are the same direction which is a direction parallel to the Y axis and a direction directed from the negative side to the positive side of the Y axis.

In this way, in this embodiment, the air blowing direction (the direction D1 and the direction D2) in the fans (the fan F1 and the fan F2) is a direction in which a wind is sent out from the inside of the housing 11.

Here, a plurality of vent holes (for example, a plurality of small holes) are provided on the surface A2 which is opposite to the surface A11 side on which the fan F1 and the fan F2 are disposed. Accordingly, the fan F1 and the fan F2 can suck air in the housing 11.

These vent holes may be provided, for example, in another surface in addition to the surface A2 or may be provided in another surface instead of the surface A2.

In this embodiment, the input terminal 31 and the output terminal 32 are disposed on the surface A2 side of the housing 11.

The input terminal 31 and the output terminal 32 may be disposed at different positions.

### <Positional Relationship Between Two Coils>

A positional relationship among the coil C1, the coil C2, and the pedestal 53 will be described below in detail.

In this embodiment, the same positional relationship as the positional relationship among the coil C1, the coil C2, and the pedestal 53 is applied as a positional relationship among the coil C11, the coil C12, and the pedestal 63, but is not necessarily applied thereto.

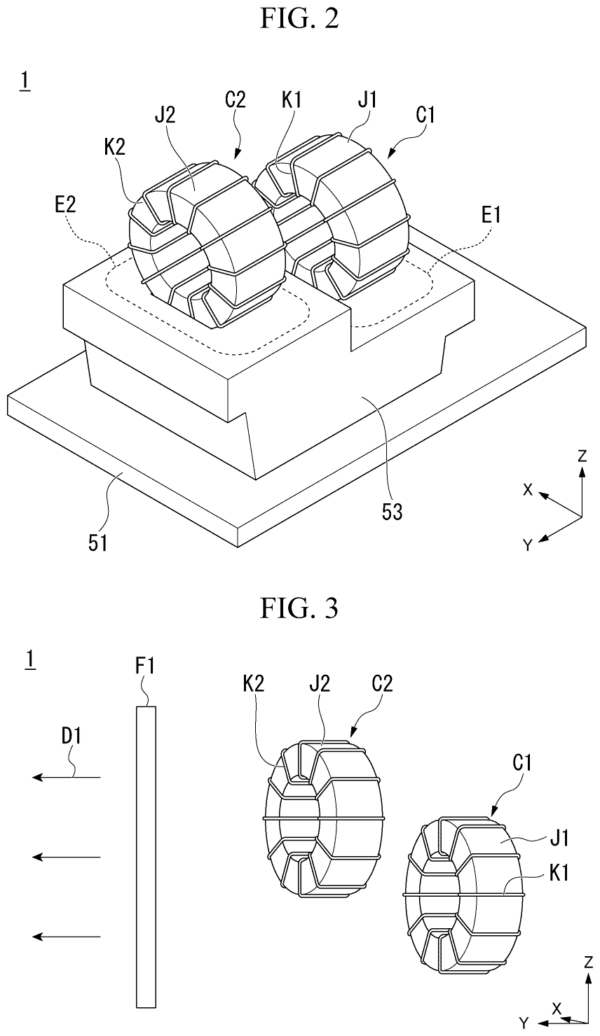

FIG. 2 is a diagram illustrating an example of a positional relationship among two coils (the coil C1 and the coil C2), the pedestal 53, and the substrate 51 according to a first embodiment.

In FIG. 2, for the purpose of convenience of explanation, the same XYZ orthogonal coordinate axes as illustrated in FIG. 1 are illustrated.

In the example illustrated in FIG. 2, parts other than two coils (the coil C1 and the coil C2), the pedestal 53, and the substrate 51 and the housing 11 are not illustrated.

In this embodiment, the coil C1 and the coil C2 have a configuration in which one coil is divided into two coils (that is, the coil C1 and the coil C2) such that the same function as one coil can be achieved. In this embodiment, one coil is equally divided into two coils, and the coil C1 and the coil C2 have the same size, for example, the core J1 and the core J2 have the same size.

Here, the one coil which is divided may be, for example, a resonance coil or another coil. The divided coils may be referred to as, for example, sub-coils.

The coil C1 and the coil C2 may not be understood to be coils into which one coil is divided, that is, may be understood to be independent coils.

Each of the coil C1 and the coil C2 includes two terminals.

In this embodiment, the coil C1 and the coil C2 are connected in series or in parallel. In this embodiment, the coil C1 and the coil C2 are electrically connected via the substrate 51 by soldering. A configuration in which another circuit part (for example, a resistor) is provided between the coil C1 and the coil C2 may be employed.

In this embodiment, illustration and detailed description of a connection state (a wiring state) between the coil C1 and the coil C2 and a connection state (a wiring state) between other circuit parts will be omitted.

In this embodiment, the coil C1 and the coil C2 are disposed at positions which are successively arranged and are disposed to be adjacent to each other.

The positional relationship between the coil C1 and the coil C2 may be referred to as adjacency.

In this embodiment, the pedestal 53 is disposed on the substrate 51.

The pedestal 53 has a height in a direction parallel to the Z axis and includes the mounting part E1 on which the coil C1 is disposed and the mounting part E2 on which the coil C2 is disposed.

Here, in the positional relationship between two coils (the coil C1 and the coil C2) according to this embodiment, the mounting part E1 and the coil C1 are disposed on the negative side of the Y axis (upstream in the wind direction), and the mounting part E2 and the coil C2 are disposed on the positive side of the Y axis (downstream in the wind direction).

In this embodiment, two coils (the coil C1 and the coil C2) are disposed at different positions in a direction (a height direction) parallel to the Z axis and a direction parallel to the Y axis, but are disposed at the same position in a direction parallel to the X axis.

In this way, in the air blowing direction (the direction D1 and the direction D2) of the fans (the fan F1 and the fan F2), the coil C2 is disposed at a position closer to the fans (the fan F1 and the fan F2) than the coil C1.

The mounting part E1 is located on the top surface of the pedestal 53 and has a shape in which a part of the side surface of the coil C1 (a part of the side surface of the toroidal shape of the core JI on which the winding K1 is wound) is housed. The coil C1 is housed above the mounting part E1 such that the circular surface of the toroidal core J1 is parallel (or almost parallel) to the XZ plane.

The mounting part E2 is located on the top surface of the pedestal 53 and has a shape in which a part of the side surface of the coil C2 (a part of the side surface of the toroidal shape of the core J2 on which the winding K2 is wound) is housed. The coil C2 is housed above the mounting part E2 such that the circular surface of the toroidal core J2 is parallel (or almost parallel) to the XZ plane.

In this embodiment, for the purpose of convenience of explanation, a part other than two circular surfaces of a toroidal shape is referred to as a side surface.

In this embodiment, the position in the height direction of the mounting part E2 is higher than the position in the height direction of the mounting part E1.

That is, the distance of the mounting part E2 from the substrate 51 is larger than a distance of the mounting part E1 from the substrate 51. That is, the height of the mounting part E2 from the surface of the substrate 51 (the distance of separation from the surface) is larger than the height of the mounting part E1 from the surface of the substrate 51 (the distance separated from the surface). Accordingly, in this embodiment, a portion located at the top (a top portion) of the coil C2 is higher than a portion located at the top (a top portion) of the coil C1.

In this way, the distance of the coil C2 disposed on the substrate 51 from the substrate 51 is larger than the distance of the coil C1 disposed on the substrate 51 from the substrate 51.

FIG. 3 is a diagram illustrating an example of a positional relationship among two coils (the coil C1 and the coil C2) and the wind direction D1 of the fan F1 according to the first embodiment.

In FIG. 3, for the purpose of convenience of explanation, the same XYZ orthogonal coordinate axes as illustrated in FIG. 1 are illustrated.

In the example illustrated in FIG. 3, parts other than two coils (the coil C1 and the coil C2) and the fan F1 and the housing 11 are not illustrated.

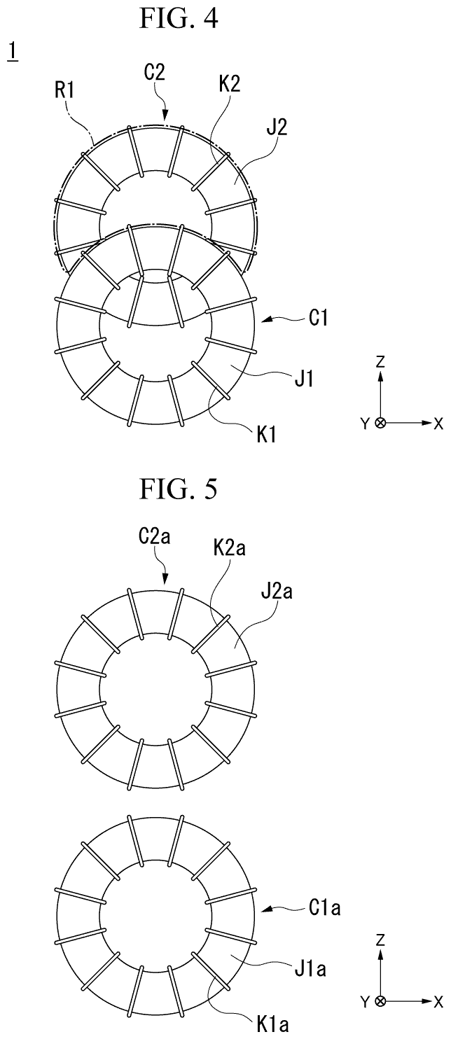

FIG. 4 is a diagram illustrating an example of a positional relationship between two coils (the coil C1 and the coil C2) when seen at a viewpoint based on the wind direction D1 of the fan F1 (which is true of the wind direction D2 of the fan F2) according to the first embodiment.

In FIG. 4, for the purpose of convenience of explanation, the same XYZ orthogonal coordinate axes as illustrated in FIG. 1 are illustrated.

In the example illustrated in FIG. 4, parts other than two coils (the coil C1 and the coil C2) and the housing 11 are not illustrated.

In this embodiment, the coils (the coil C1 and the coil C2) obtained by dividing one coil into two coils are mounted on two mounting parts (the mounting part E1 and the mounting part E2) having a height difference in the pedestal 53.

The mounting part E1 and the mounting part E2 have a difference in the height direction (a height difference), and the mounting part E2 which is nearer when seen from the surface A1 side on which the fans (the fan F1 and the fan F2) are provided is located at a higher position than the other mounting part E1.

Here, when it is mentioned that it is located nearer when seen from the surface A1 side, it means that the distance from the surface A1 (for example, the distance in a direction perpendicular to the surface A1) is smaller.

As illustrated in FIGS. 3 and 4, when seen at a viewpoint in the wind direction D1 of the fan F1 (which is true of the wind direction D2 of the fan F2), the whole circular surface (the surface on the negative side of the Y axis) of the coil C1 is seen, a part of the circular surface (the surface on the negative side of the Y axis) of the coil C2 is seen, and the other part thereof is not seen.

That is, in this embodiment, a wind (winds in the direction D1 and the direction D2) formed by the fans (the fan F1 and the fan F2) directly hits at least a part of each of two coils (the coil C1 and the coil C2). In the example illustrated in FIGS. 3 and 4, the wind directly hits the whole circular surface (the surface on the negative side of the Y axis) of the coil C1, and the wind directly hits at least a part of the circular surface (the surface on the negative side of the Y axis) of the coil C2.

In this way, in this embodiment, at least a part of each of the coil C1 and the coil C2 is included in the field of view at which the coil C1 and the coil C2 are seen in the same direction as the air blowing direction (the direction D1 and the direction D2) in the fans (the fan F1 and the fan F2).

In the example illustrated in FIG. 4, a region (a rough area) of the coil C2 which is hit by a wind is defined as a region R1. The region R1 is schematic and is not necessarily a strict region.

With this configuration, heat dissipation of the coils (the coil C1 and the coil C2) and cooling of the coils (the coil C1 and the coil C2) are performed using the air flows based on the fans (the fan F1 and the fan F2) mounted in the power supply device 1 including the housing 11.

In this embodiment, positions of two coils (the coil C1 and the coil C2) are set with respect to the wind direction (the direction D1 and the direction D2) at the positions at which the fan F1 and the fan F2 are located.

Since another part is actually present near two coils (the coil C1 and the coil C2) or the like, the direction of the wind hitting the two coils (the coil C1 and the coil C2) may deviate slightly from the wind direction (the direction D1 and the direction D2) at the positions at which the fan F1 and the fan F2 are present. However, in this embodiment, an effect of a wind directly hitting the coils (the coil C1 and the coil C2) is considered to be higher in comparison with arrangement of two coils in the related art (for example, arrangement in which two coils are completely overlapped at the viewpoint illustrated in FIG. 4).

As described above, with the power supply device 1 according to this embodiment, when a plurality of coils (the coil C1 and the coil C2) are disposed, for example, to be adjacent to each other, it is possible to effectively cool the coils using the air blower (the fan F1 and the fan F2 in this embodiment).

In this way, in this embodiment, it is possible to provide an effective heat dissipation structure of coils.

For example, it is conceivable that an amount of generated heat is decreased by dividing one coil into two coils, and a degree of decrease in the amount of generated heat may not be sufficient. Therefore, in this embodiment, it is possible to sufficiently decrease emission of heat of the coils (the coil C1 and the coil C2) by changing the arrangement of two divided coils (the coil C1 and the coil C2) as a new configuration.

Here, the housing 11 may have an arbitrary shape.

In this embodiment, for the purpose of convenience of explanation, the bottom surface (surface A3) of the housing 11 is disposed on a plane (for example, a floor surface or a surface of a table) perpendicular to the gravitational direction, but the housing 11 may be disposed in another direction.

In this embodiment, the fans (the fan F1 and the fan F2) are used as an example of an air blower, but another air blower may be used.

For example, a device that performs forced-air cooling such as a fan is used as the air blower.

In this embodiment, a shape in which the coils (the coil C1 and the coil C2) mounted on the pedestal 53 protrude from the pedestal 53 (protrudes upward in this embodiment) is used as the shape of the pedestal 53, but another shape may be used as the shape of the pedestal 53.

In this embodiment, the common pedestal 53 (the unified pedestal 53) is used for two coils (the coil C1 and the coil C2), but, for example, different pedestals (that is, separated pedestals) may be used for the coils.

In this embodiment, a configuration example in which the pedestal 53 cuts off a wind is described, but, for example, a configuration not using the pedestal 53 may be employed or the coils (the coil C1 and the coil C2) may be held by another arbitrary mechanism.

In the positional relationship between two coils (the coil C1 and the coil C2) illustrated in FIG. 4, when the pedestal 53 is assumed not to be present, for example, there may be a configuration in which at least parts of the two coils (the coil C1 and the coil C2) are directly hit by wind even when the wind directions (the direction D1 and the direction D2) of the fans (the fan F1 and the fan F2) are different directions (for example, opposite directions).

### <Modified Examples of First Embodiment>

FIG. 5 is a diagram illustrating an example of a positional relationship between two coils when seen at a viewpoint based on the wind directions (the direction D1 and the direction D2) of the fans (the fan F1 and the fan F2) according to a modified example of the first embodiment.

In FIG. 5, for the purpose of convenience of explanation, the same XYZ orthogonal coordinate axes as illustrated in FIG. 1 are illustrated.

In the example illustrated in FIG. 5, a coil C1a including a core J1a and a winding K2a and a coil C2a including a core J2a and a winding K2a are illustrated.

The example illustrated in FIG. 5 corresponds to the example illustrated in FIG. 4 according to the first embodiment and is a modified example thereof.

Here, the coil C1a corresponds to the coil C1 illustrated in FIG. 4 and may have the same structure as the coil C1.

The coil C2a corresponds to the coil C2 illustrated in FIG. 4 and may have the same structure as the coil C2.

The example illustrated in FIG. 5 is different from the first embodiment in the positional relationship between two coils (the coil C1a and the coil C2a).

As illustrated in FIG. 5, when seen at a viewpoint based on the wind direction D1 of the fan F1 (which is true of the wind direction D2 of the fan F2), the two coils (the coil C1a and the coil C2a) are not overlapped, the whole circular surface (the surface on the negative side of the Y axis) of the coil C1a is seen, and the whole circular surface (the surface on the negative side of the Y axis) of the coil C2a is seen.

That is, in the example illustrated in FIG. 5, winds formed by the fans (the fan F1 and the fan F2) (the winds in the direction D1 and the direction D2) directly hit the whole circular surfaces of the two coils (the coil C1a and the coil C2a).

With this configuration, heat dissipation of the coils (the coil C1a and the coil C2a) and cooling of the coils (the coil C1a and the coil C2a) are performed using the air flows based on the fans (the fan F1 and the fan F2) mounted in the power supply device 1 including the housing 11.

In the positional relationship between two coils (the coil C1a and the coil C2a) illustrated in FIG. 5, when the pedestal 53 is assumed not to be present, for example, there may be a configuration in which at least parts of the two coils (the coil C1a and the coil C2a) are directly hit by wind even when the wind directions (the direction D1 and the direction D2) of the fans (the fan F1 and the fan F2) are different directions (for example, opposite directions).

The configuration example of the first embodiment will be described below. The power supply device 1 includes a first coil (the coil C1 in this embodiment), a second coil (the coil C2 in this embodiment), a pedestal (the pedestal 53 in this embodiment), an air blower (the fan F1 and the fan F2 in this embodiment), a substrate (the substrate 51 in this embodiment), and a housing (the housing 11 in this embodiment).

The first coil includes a first core (the core J1 in this embodiment) and a first winding (the winding K1 in this embodiment) wound on the first core.

The second coil includes a second core (the core J2 in this embodiment) and a second winding (the winding K2 in this embodiment) wound on the second core.

The pedestal mounts the first coil and the second coil thereon.

The distance (the height in this embodiment) of the second coil mounted on the pedestal disposed on the substrate from the substrate is larger than the distance of the first coil mounted on the pedestal disposed on the substrate from the substrate.

The air blower is disposed such that the second coil is located on the nearer side (the first coil is located on the deeper side). The air blower blows air outward from the inside of the housing.

Here, the pedestal disposed on the substrate includes a first mounting part (the mounting part E1 in this embodiment) on which the first coil is mounted and a second mounting part (the mounting part E2 in this embodiment) on which the second coil is mounted. The distance (the height in this embodiment) of the second mounting part from the substrate is larger than the distance of the first mounting part from the substrate.

### Second Embodiment

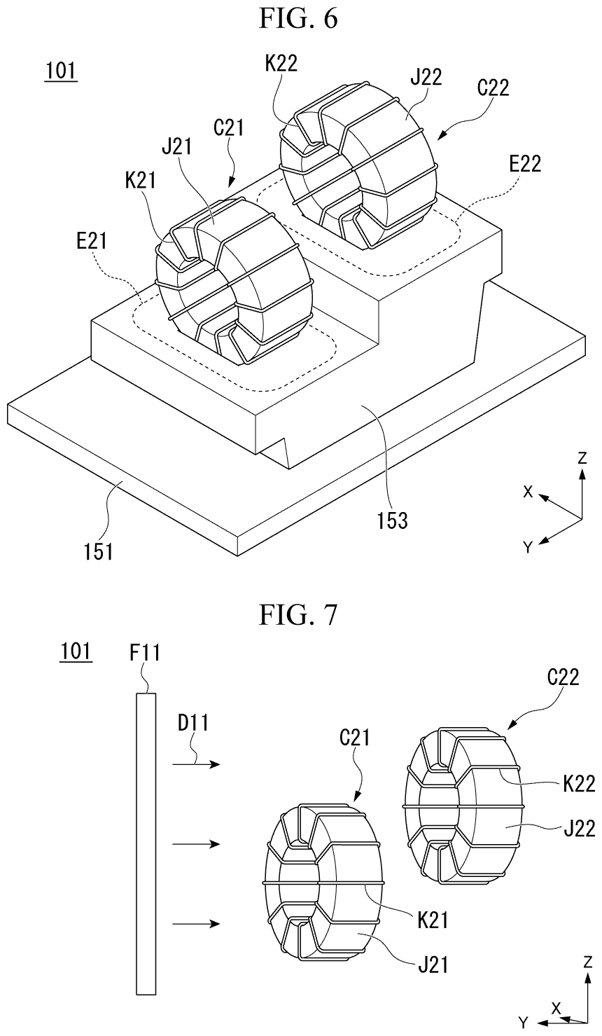

A second embodiment will be described below with reference to FIGS. 6 and 7.

In the second embodiment, a configuration example which is different from the first embodiment in the positional relationship between two coils and wind directions of fans will be described.

In this embodiment, a configuration different from that of the power supply device 1 illustrated in FIG. 1 will be described in detail, and a detailed description of the same configuration will be omitted.

In this embodiment, for the purpose of convenience of explanation, a power supply device 101, a fan F11, a wind direction D11 of the fan F11, a substrate 151, a pedestal 153 including a mounting part E21 and a mounting part E22, a coil C21 including a core J21 and a winding K21, and a coil C22 including a core J22 and a winding K22 are used instead of the power supply device 1, the fan F1, the wind direction D1 of the fan F1, the substrate 51, the pedestal 53 including the mounting part E1 and the mounting part E2, the coil C1 including the core J1 and the winding K1, and the coil C2 including the core J2 and the winding K2 illustrated in FIG. 1.

In this embodiment, a fan (not illustrated) that forms a wind in the same direction as the wind direction D11 of the fan F11 can be provided instead of the fan F2 illustrated in FIG. 1.

In this embodiment, for the purpose of convenience of explanation, the other constituents will be referred to by the same reference signs as illustrated in FIG. 1.

### <Positional Relationship Between Two Coils>

A positional relationship among the coil C21, the coil C22, and the pedestal 153 will be described below in detail.

In this embodiment, the same positional relationship as the positional relationship among the coil C21, the coil C22, and the pedestal 153 may be applied as a positional relationship among the coil C11, the coil C12, and the pedestal 63 in FIG. 1. In this case, the constituent parts of the coil C11, the coil C12, and the pedestal 63 illustrated in FIG. 1 are replaced. However, the same positional relationship as the positional relationship among the coil C21, the coil C22, and the pedestal 153 may not be applied as the positional relationship among the coil C11, the coil C12, and the pedestal 63 illustrated in FIG. 1.

FIG. 6 is a diagram illustrating an example of a positional relationship among two coils (the coil C21 and the coil C22), the pedestal 153, and the substrate 151 according to the second embodiment.

In FIG. 6, for the purpose of convenience of explanation, the same XYZ orthogonal coordinate axes as illustrated in FIG. 1 are illustrated.

In the example illustrated in FIG. 6, parts other than two coils (the coil C21 and the coil C22), the pedestal 153, and the substrate 151 and the housing 11 are not illustrated.

In this embodiment, the coil C21 and the coil C22 have a configuration in which one coil is divided into two coils (that is, the coil C21 and the coil C22) such that the same function as one coil can be achieved. In this embodiment, one coil is equally divided into two coils, and the coil C21 and the coil C22 have the same size, for example, the core J21 and the core J22 have the same size.

Here, the one coil which is divided may be, for example, a resonance coil or another coil.

Each of the coil C21 and the coil C22 includes two terminals.

In this embodiment, the coil C21 and the coil C22 are connected in series or in parallel.

In this embodiment, the coil C21 and the coil C22 are electrically connected via the substrate 151 by soldering. A configuration in which another circuit part (for example, a resistor) is provided between the coil C11 and the coil C12 may be employed.

In this embodiment, illustration and detailed description of a connection state (a wiring state) between the coil C21 and the coil C22 and a connection state (a wiring state) between other circuit parts will be omitted.

In this embodiment, the coil C21 and the coil C22 are disposed at positions which are successively arranged and are disposed to be adjacent to each other.

The positional relationship between the coil C21 and the coil C22 may be referred to as adjacency.

In this embodiment, the pedestal 153 is disposed on the substrate 151.

The pedestal 153 has a height in a direction parallel to the Z axis and includes the mounting part E21 on which the coil C21 disposed and the mounting part E22 on which the coil C22 is disposed.

Here, in the positional relationship between two coils (the coil C21 and the coil C22) according to this embodiment, the mounting part E21 and the coil C21 are disposed on the positive side of the Y axis (upstream in the wind direction), and the mounting part E22 and the coil C22 are disposed on the negative side of the Y axis (downstream in the wind direction).

In this embodiment, two coils (the coil C21 and the coil C22) are disposed at different positions in a direction (a height direction) parallel to the Z axis and a direction parallel to the Y axis, but are disposed at the same position in a direction parallel to the X axis.

In this way, in the air blowing direction (the direction D11) of the fans (the fan F11 and the other fan), the coil C22 is disposed at a position farther from the fans (the fan F11 and the other fan) than the coil C21.

The mounting part E21 is located on the top surface of the pedestal 153 and has a shape in which a part of the side surface of the coil C21 (a part of the side surface of the toroidal shape of the core J21 on which the winding K21 is wound) is housed. The coil C21 is housed above the mounting part E21 such that the circular surface of the toroidal core J21 is parallel (or almost parallel) to the XZ plane.

The mounting part E22 is located on the top surface of the pedestal 153 and has a shape in which a part of the side surface of the coil C22 (a part of the side surface of the toroidal shape of the core J22 on which the winding K22 is wound) is housed. The coil C22 is housed above the mounting part E22 such that the circular surface of the toroidal core J22 is parallel (or almost parallel) to the XZ plane.

In this embodiment, for the purpose of convenience of explanation, a part other than two circular surfaces of a toroidal shape is referred to as a side surface.

In this embodiment, the position in the height direction of the mounting part E22 is higher than the position in the height direction of the mounting part E21.

That is, the distance of the mounting part E22 from the substrate 151 is larger than a distance of the mounting part E21 from the substrate 151. That is, the height of the mounting part E22 from the surface of the substrate 151 (the distance separated from the surface) is larger than the height of the mounting part E21 from the surface of the substrate 151 (the distance separated from the surface).

Accordingly, in this embodiment, a portion located at the top (a top portion) of the coil C22 is higher than a portion located at the top (a top portion) of the coil C21.

In this way, the distance of the coil C22 disposed on the substrate 151 from the substrate 151 is larger than the distance of the coil C21 disposed on the substrate 151 from the substrate 151.

FIG. 7 is a diagram illustrating an example of a positional relationship among two coils (the coil C21 and the coil C22) and the wind direction D11 of the fan F11 according to the second embodiment.

In FIG. 7, for the purpose of convenience of explanation, the same XYZ orthogonal coordinate axes as illustrated in FIG. 1 are illustrated.

In the example illustrated in FIG. 7, parts other than two coils (the coil C21 and the coil C22) and the fan F11 and the housing 11 are not illustrated.

In this embodiment, the fans (the fan F11 and the other fan) sucks air outside of the housing 11 from the surface Al side and blows the air inward, whereby a wind (an air flow) is generated in the housing 11.

In FIG. 7, for the purpose of convenience of explanation, a direction D11 of a wind which is formed by the fan F11 is illustrated. In this embodiment, the wind direction (the direction D11) is a direction which is parallel to the Y axis and which is directed from the positive side to the negative side of the Y axis.

In this way, in this embodiment, the air blowing direction (the direction D11) in the fans (the fan F11 and the other fan) is a direction in which air is blown inward from the outside of the housing 11.

In this embodiment, the coils (the coil C21 and the coil C22) obtained by dividing one coil into two coils are mounted on two mounting parts (the mounting part E21 and the mounting part E22) having a height difference in the pedestal 153.

The mounting part E21 and the mounting part E22 have a difference in the height direction (a height difference), and the mounting part E22 which is deeper when seen from the surface A1 side on which the fans (the fan F11 and the other fan in which the wind direction is opposite to that of the fan F2 in FIG. 1) are provided is located at a higher position than the other mounting part E21.

Here, when it is mentioned that it is located deeper when seen from the surface A1 side, it means that the distance from the surface A1 (for example, the distance in a direction perpendicular to the surface A1) is larger.

As illustrated in FIG. 7, when seen at a viewpoint in the wind direction D11 of the fan F11 (which is true of the wind direction of the other fan), the whole circular surface (the surface on the positive side of the Y axis) of the coil C21 is seen, a part of the circular surface (the surface on the positive side of the Y axis) of the coil C22 is seen, and the other part thereof is not seen.

That is, in this embodiment, a wind (wind in the direction D11) formed by the fans (the fan F11 and the other fan) directly hits at least a part of each of two coils (the coil C21 and the coil C22). In the example illustrated in FIG. 7, the wind directly hits the whole circular surface (the surface on the positive side of the Y axis) of the coil C21, and the wind directly hits at least a part of the circular surface (the surface on the positive side of the Y axis) of the coil C22.

In this way, in this embodiment, at least a part of each of the coil C21 and the coil C22 is included in the field of view at which the coil C21 and the coil C22 are seen in the same direction as the air blowing direction (the direction D11) in the fans (the fan F11 and the other fan).

With this configuration, heat dissipation of the coils (the coil C21 and the coil C22) and cooling of the coils (the coil C21 and the coil C22) are performed using the air flows based on the fans (the fan F11 and the other fan) mounted in the power supply device 101 including the housing 11.

In this embodiment, positions of two coils (the coil C21 and the coil C22) are set with respect to the wind direction (the direction D11) at the positions at which the fans (the fan F11 and the other fan) are located.

Since another part is actually present near two coils (the coil C21 and the coil C22) or the like, the direction of the wind hitting the two coils (the coil C21 and the coil C22) may deviate slightly from the wind direction (the direction D11) at the positions at which the fans (the fan F11 and the other fan) are present. However, in this embodiment, an effect of a wind directly hitting the coils (the coil C21 and the coil C22) is considered to be higher in comparison with arrangement of two coils in the related art (for example, arrangement in which two coils are completely overlapped at the viewpoint parallel to the Y axis).

As described above, with the power supply device 101 according to this embodiment, when a plurality of coils (the coil C21 and the coil C22) are disposed, for example, to be adjacent to each other, it is possible to effectively cool the coils using the air blower (the fan F11 and the other fan in this embodiment).

In this way, in this embodiment, it is possible to provide an effective heat dissipation structure of coils.

For example, it is conceivable that an amount of generated heat is decreased by dividing one coil into two coils, and a degree of decrease in the amount of generated heat may not be sufficient. Therefore, in this embodiment, it is possible to sufficiently decrease emission of heat of the coils (the coil C21 and the coil C22) by changing the arrangement of two divided coils (the coil C21 and the coil C22) as a new configuration.

In this embodiment, similarly to the first embodiment, the positional relationship in which two coils (the coil C21 and the coil C22) do not overlap when seen at a viewpoint parallel to the Y axis as illustrated in FIG. 5 may be employed.

In this embodiment, a shape in which the coils (the coil C21 and the coil C22) mounted on the pedestal 153 protrude from the pedestal 153 (protrudes upward in this embodiment) is used as the shape of the pedestal 153, but another shape may be used as the shape of the pedestal 153.

In this embodiment, the common pedestal 153 (the unified pedestal 153) is used for two coils (the coil C21 and the coil C22), but, for example, different pedestals (that is, separated pedestals) may be used for the coils.

In this embodiment, a configuration example in which the pedestal 153 cuts off a wind is described, but, for example, a configuration not using the pedestal 153 may be employed or the coils (the coil C21 and the coil C22) may be held by another arbitrary mechanism.

In the positional relationship between two coils (the coil C21 and the coil C22) illustrated in FIGS. 6 and 7, when the pedestal 153 is assumed not to be present, for example, there may be a configuration in which at least parts of the two coils (the coil C21 and the coil C22) are directly hit by wind even when the wind directions (the direction D11) of the fans (the fan F11 and the other fan) are different directions (for example, opposite directions).

The configuration example of the second embodiment will be described below.

The power supply device 101 includes a first coil (the coil C21 in this embodiment), a second coil (the coil C22 in this embodiment), a pedestal (the pedestal 153 in this embodiment), an air blower (the fan F11 and the other fan in this embodiment), a substrate (the substrate 151 in this embodiment), and a housing (the housing 11 in this embodiment).

The first coil includes a first core (the core J21 in this embodiment) and a first winding (the winding K21 in this embodiment) wound on the first core.

The second coil includes a second core (the core J22 in this embodiment) and a second winding (the winding K22 in this embodiment) wound on the second core.

The pedestal mounts the first coil and the second coil thereon.

The distance (the height in this embodiment) of the second coil mounted on the pedestal disposed on the substrate from the substrate is larger than the distance of the first coil mounted on the pedestal disposed on the substrate from the substrate.

The air blower is disposed such that the second coil is located on the deeper side (the first coil is located on the nearer side). The air blower blows air inward from the outside of the housing.

Here, the pedestal disposed on the substrate includes a first mounting part (the mounting part E21 in this embodiment) on which the first coil is mounted and a second mounting part (the mounting part E22 in this embodiment) on which the second coil is mounted. The distance (the height in this embodiment) of the second mounting part from the substrate is larger than the distance of the first mounting part from the substrate.

### Third Embodiment

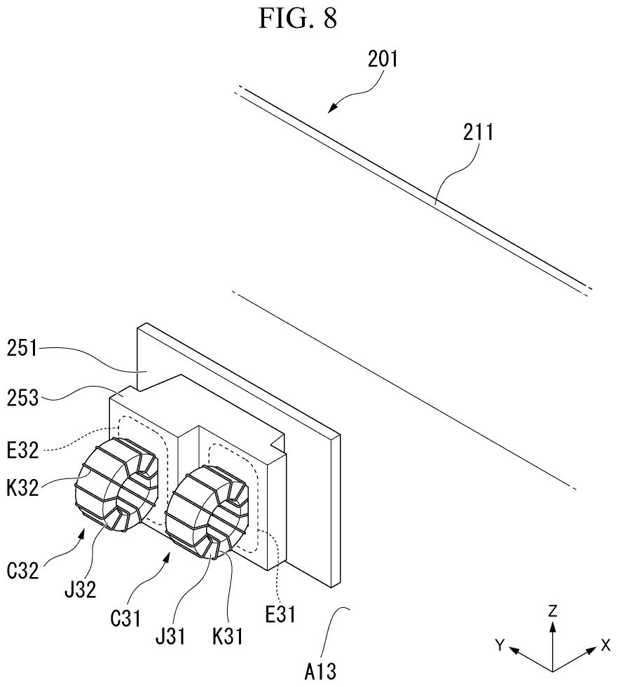

A third embodiment will be described below with reference to FIG. 8.

In the third embodiment, a configuration example which is different from the first embodiment in the position of the substrate relative to the housing will be described. In this embodiment, a configuration different from that of the power supply device 1 illustrated in FIG. 1 will be described in detail, and a detailed description of the same configuration will be omitted.

In this embodiment, for the purpose of convenience of explanation, a power supply device 201, a housing 211, a surface A13 of the housing, a substrate 251, a pedestal 253 including a mounting part E31 and a mounting part E32, a coil C31 including a core J31 and a winding K31, and a coil C32 including a core J32 and a winding K32 are used instead of the power supply device 1, the housing 11, the surface A3 of the housing, the substrate 51, the pedestal 53 including the mounting part E1 and the mounting part E2, the coil C1 including the core JI and the winding K1, and the coil C2 including the core J2 and the winding K2 illustrated in FIG. 1.

In this embodiment, for the purpose of convenience of explanation, the other constituents will be referred to by the same reference signs as illustrated in FIG. 1.

### <Positional Relationship Among Substrate, Pedestal, and Two Coils>

A positional relationship among the substrate 251, the pedestal 253, and two coils (the coil C31 and the coil C32) will be described below in detail.

In this embodiment, the same positional relationship as the positional relationship among the substrate 251, the pedestal 253, and two coils (the coil C31 and the coil C32) may be applied as the positional relationship among the substrate 61, the pedestal 63, and two coils (the coil C11, the coil C12) in FIG. 1. In this case, the constituent parts of the substrate 61, the pedestal 63, and the two coils (the coil C11 and the coil C12) illustrated in FIG. 1 are replaced. However, the same positional relationship among the substrate 251, the pedestal 253, and two coils (the coil C31 and the coil C32) may not be applied as the positional relationship among the substrate 61, the pedestal 63, and two coils (the coil C11, the coil C12) illustrated in FIG. 1.

FIG. 8 is a diagram illustrating an example of the positional relationship among the substrate 251, the pedestal 253, and two coils (the coil C31 and the coil C32) according to the third embodiment.

In FIG. 8, for the purpose of convenience of explanation, the same XYZ orthogonal coordinate axes as illustrated in FIG. 1 are illustrated.

In the example illustrated in FIG. 8, parts other than the housing 211, the substrate 251, the pedestal 253, and two coils (the coil C31 and the coil C32) in the power supply device 201 are not illustrated.

In this embodiment, the substrate 251 has a planar panel shape, and a planar surface thereof is disposed parallel (or almost parallel) to the YZ plane and perpendicular (or almost perpendicular) to the bottom surface (the surface A13) of the housing 211.

In the example illustrated in FIG. 8, the positional relationship of the pedestal 253 and two coils (the coil C31 and the coil C32) relative to the substrate 251 is the same as the positional relationship of the pedestal 53 and two coils (the coil C1 and the coil C2) relative to the substrate 51 illustrated in FIG. 1.

In the example illustrated in FIG. 8, the pedestal 253 and two coils (the coil C31 and the coil C32) protrude to the negative side of the X axis from the planar surface of the substrate 251, but, for example, a configuration in which the pedestal 253 and two coils (the coil C31 and the coil C32) protrude to the positive side of the X axis from the planar surface of the substrate 251 may be employed.

In this embodiment, the same positional relationship as the positional relationship in the first embodiment is applied as the positional relationship of the pedestal 253 and two coils (the coil C31 and the coil C32) relative to the substrate 251, but, for example, the same positional relationship as the positional relationship in the second embodiment may be applied.

As described above, with the power supply device 201 according to this embodiment, when a plurality of coils (the coil C31 and the coil C32) are disposed, for example, to be adjacent to each other, it is possible to effectively cool the coils using the air blower (the fan in this embodiment).

In this way, in this embodiment, it is possible to provide an effective heat dissipation structure of coils.

In the first embodiment and the second embodiment, the planar surface of the substrate (the substrate 51 and the substrate 151) is disposed to be parallel (or almost parallel) to the bottom surface (the surface A3) of the housing 11. In the third embodiment, the planar surface of the substrate 251 is perpendicular (or almost perpendicular) to the bottom surface (the surface A13) of the housing 211, but another mode may be used as the positional relationship between the planar surface of the substrate and the bottom surface of the housing (an angle formed therebetween).

In the third embodiment, the planar surface of the substrate 251 is disposed parallel (or almost parallel) to the YZ plane, but the present disclosure is not limited to this positional relationship.

### [Other Configuration Examples]

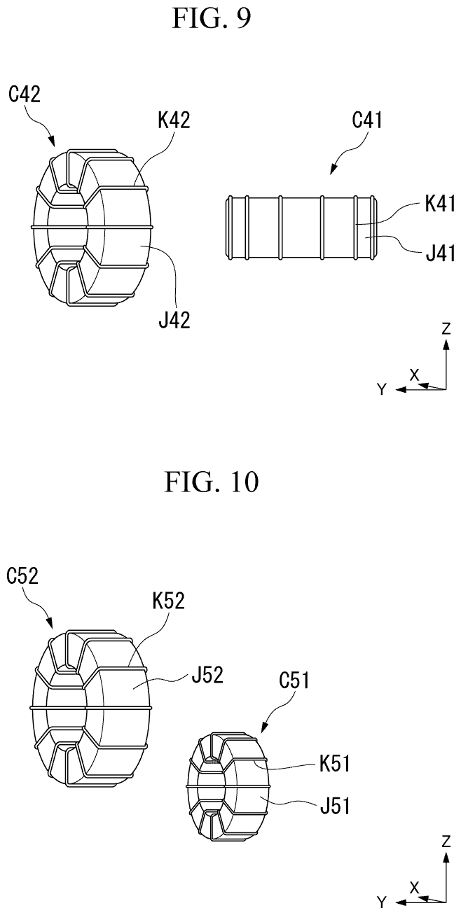

FIG. 9 is a diagram illustrating another configuration example of a positional relationship between two coils.

In FIG. 9, for the purpose of convenience of explanation, the same XYZ orthogonal coordinate axes as illustrated in FIG. 1 are illustrated.

In FIG. 9, a coil C41 including a core J41 and a winding K41 and a coil C42 including a core J42 and a winding K42 are illustrated.

In the example illustrated in FIG. 9, the coil C41 and the coil C42 are disposed such that a circular surface of the core J41 of the coil C41 and a circular surface of the core J42 of the coil C42 are perpendicular to each other.

This positional relationship between two coils (the coil C41 and the coil C42) may be used, for example, instead of the positional relationship between two coils (for example, the coil C1 and the coil C2) in the first embodiment, may be used instead of the positional relationship between two coils (for example, the coil C21 and the coil C22) in the second embodiment, or may be used instead of the positional relationship between two coils (for example, the coil C31 and the coil C32) in the third embodiment.

FIG. 10 is a diagram illustrating another configuration example associated with the sizes of two coils.

In FIG. 10, for the purpose of convenience of explanation, the same XYZ orthogonal coordinate axes as illustrated in FIG. 1 are illustrated.

In FIG. 10, a coil C51 including a core J51 and a winding K51 and a coil C52 including a core J52 and a winding K52 are illustrated.

In the example illustrated in FIG. 10, the coil C51 and the coil C52 have different sizes, and, for example, the core J51 and the core J52 have different sizes.

In the example illustrated in FIG. 10, the coil C51 and the coil C52 have similar shapes, and the two coils may have, for example, shapes not similar to each other. Here, the coil C51 and the coil C52 may be coils into which one coil is unequally divided (that is, the coil C51 and the coil C52).

Two coils having different sizes (the coil C51 and the coil C52 in the example illustrated in FIG. 10) may be used, for example, instead of two coils (for example, the coil C1 and the coil C2) in the first embodiment, may be used instead of two coils (for example, the coil C21 and the coil C22) in the second embodiment, or may be used instead of two coils (for example, the coil C31 and the coil C32) in the third embodiment.

The positional relationship between two coils having different sizes is not limited to the example illustrated in FIG. 10, and another positional relationship may be used.

For example, in the example illustrated in FIG. 10, two coils are overlapped partially in the wind direction of the fan, and a positional relationship in which two coils are not overlapped at all may be used, for example, similarly to the example illustrated in FIG. 5.

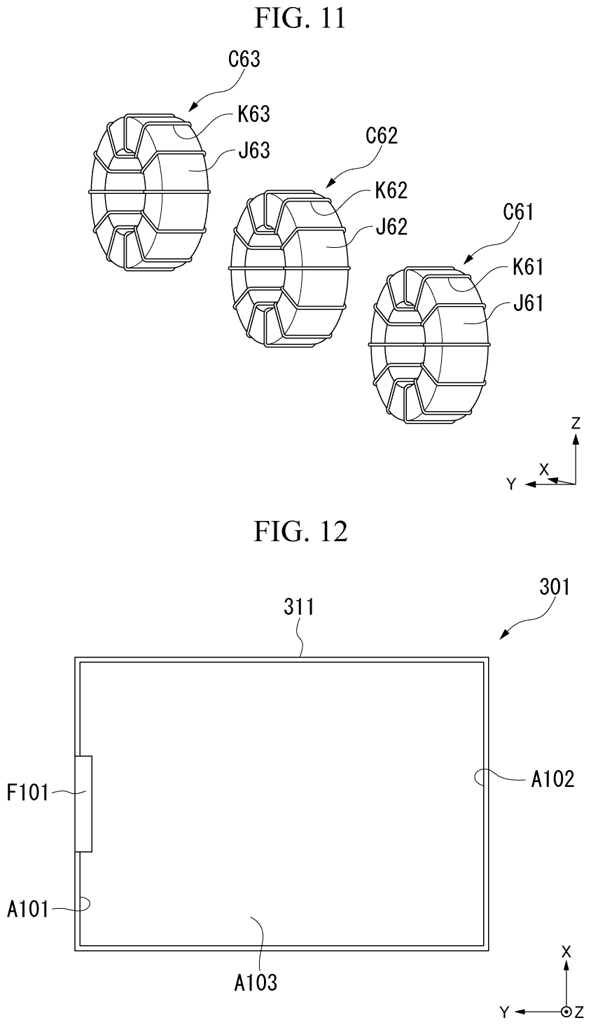

FIG. 11 is a diagram illustrating an example of a positional relationship among three coils.

In FIG. 11, for the purpose of convenience of explanation, the same XYZ orthogonal coordinate axes as illustrated in FIG. 1 are illustrated.

In FIG. 11, a coil C61 including a core J61 and a winding K61, a coil C62 including a core J62 and a winding K62, and a coil C63 including a core J63 and a winding K63 are illustrated.

These three coils (the coil C61, the coil C62, and the coil C63) are disposed at positions which are successively arranged and disposed to be adjacent to each other.

The positional relationship among these three coils (the coil C61, the coil C62, and the coil C63) is set such that a wind of a fan (a wind in the same direction as the air blowing direction at the position of the fan) directly hits at least a part of each coil.

These three coils (the coil C61, the coil C62, and the coil C63) may be, for example, coils which are obtained by dividing one coil into three coils.

The positional relationship among three coils is not limited to the example illustrated in FIG. 11, and another positional relationship may be used.

In the example illustrated in FIG. 11, three coils have the same shape. However, for example, each coil may have a shape different from those of the other coils, or two coils may have the same shape and the other one coil may have a different shape.

In the example illustrated in FIG. 11, the positional relationship among three coils is described, but the same may be applied to a positional relationship among four or more coils.

That is, a positional relationship among a plurality of coils is set such that a wind of a fan (a wind in the same direction as the air blowing direction at the position of the fan) directly hits at least a part of each coil.

The plurality of coils are disposed at positions which are successively arranged and disposed to be adjacent to each other.

The plurality of coils may be, for example, coils into which one coil is divided.

The plurality of coils are connected to each other in series or in parallel.

The plurality of coils are electrically connected, via the substrate by soldering.

A position at which another circuit part (for example, a resistor) is provided may be present between the coils.

For example, this configuration including three or more coils may be used instead of the configuration including two coils (for example, the coil C1 and the coil C2) in the first embodiment, instead of the configuration including two coils (for example, the coil C21 and the coil C22) in the second embodiment, or may be used instead of the configuration including two coils (for example, the coil C31 and the coil C32) in the third embodiment,

FIG. 12 is a diagram illustrating another configuration example of a fan.

In FIG. 12, for the purpose of convenience of explanation, the same XYZ orthogonal coordinate axes as illustrated in FIG. 1 are illustrated.

In FIG. 12, a housing 311 of a power supply device 301 is illustrated at the same viewpoint as illustrated in FIG. 1.

In the example illustrated in FIG. 12, a surface A101, a surface A102, and a surface A103 are illustrated as surfaces corresponding to the surface A1, the surface A2, and the surface A3 in FIG. 1.

In the example illustrated in FIG. 12, a fan F101 provided in the power supply device 301 is illustrated. In the example illustrated in FIG. 12, other parts provided in the power supply device 301 are not illustrated.

The example illustrated in FIG. 12 is different from the example illustrated in FIG. 1 in that the power supply device 301 includes only one fan F101.

The fan F101 is provided on the surface A101 side of the housing 311.

A direction of a wind sucked and blown by the fan F101 is a direction which is parallel to the Y axis and a direction which is directed from the negative side to the positive side of the Y axis or a direction which is directed from the positive side to the negative side of the Y axis.

The fan F101 is provided at the center of the surface A101 in a direction parallel to the X axis, but may be provided at another position.

In this way, the configuration in which one fan F101 is provided in the power supply device 301 may be used instead of the configuration including two fans (the fan F1 and the fan F2) illustrated in FIG. 1.

For example, a configuration in which three or more fans are provided in the power supply device may be used.

### [Case in Which Two or More Coil Units are Provided in Power Supply Device]

For example, in the example illustrated in FIG. 1, there are a coil unit including a group of the coil C1 and the coil C2 and a coil unit including a group of the coil C11 and the coil C12, and the predetermined positional relationship according to this embodiment is applied to each of one or more of the plurality of coil units.

In this way, when a plurality of coil units are provided in the power supply device, the predetermined positional relationship according to this embodiment may be applied to one or more (which may be all) of the plurality of coil units.

In this embodiment, for the purpose of convenience of explanation, a coil unit means a “group of two or more coils” of which at least a part is directly hit by a wind.

The predetermined positional relationship according to this embodiment means a positional relationship in which at least a part of each coil is directly hit by a wind, and various positional relationships such as the positional relationship illustrated in FIGS. 2 to 4, the positional relationship illustrated in FIG. 5, the positional relationship illustrated in FIGS. 6 and 7, the positional relationship illustrated in FIG. 8, the positional relationship illustrated in FIG. 9, the positional relationship illustrated in FIG. 10, and the positional relationship illustrated in FIG. 11 may be used.

While embodiments of the present disclosure have been described above in detail with reference to the drawings, specific configurations are not limited to the embodiments, and designs or the like in a range not departing from the gist of the present disclosure are included.

### [Remarks]

(Configuration Example 1) to (Configuration Example 7) are described below.

### (Configuration Example 1)

A power supply device including a first coil, a second coil, a substrate, an air blower, and a housing that houses the first coil, the second coil, the substrate, and the air blower,
wherein the first coil and the second coil are connected in series or in parallel, and
wherein at least parts of the first coil and the second coil are included in a field of view at a viewpoint at which the first coil and the second coil are seen in the same direction as an air blowing direction of the air blower.

### (Configuration Example 2)

The power supply device according to (Configuration Example 1), wherein a second distance of the second coil disposed on the substrate from the substrate is larger than a first distance of the first coil disposed on the substrate from the substrate, and
wherein the second coil is disposed at a position closer to the air blower than the first coil, and the air blowing direction in the air blower is a direction in which air is blown outward from the inside of the housing.

### (Configuration Example 3)

The power supply device according to (Configuration Example 1), wherein a second distance of the second coil disposed on the substrate from the substrate is larger than a first distance of the first coil disposed on the substrate from the substrate, and
wherein the second coil is disposed at a position farther from the air blower than the first coil, and the air blowing direction in the air blower is a direction in which air is blown inward from the outside of the housing.

### (Configuration Example 4)

The power supply device according to any one of (Configuration Example 1) to (Configuration Example 3), further including a pedestal which is disposed on the substrate and on which the first coil and the second coil are mounted.

### (Configuration Example 5)

The power supply device according to (Configuration Example 4), wherein the pedestal includes a first mounting part on which the first coil is mounted and a second mounting part on which the second coil is mounted, and
wherein a fourth distance of the second mounting part from the substrate is larger than a third distance of the first mounting part from the substrate.

### (Configuration Example 6)

The power supply device according to any one of (Configuration Example 1) to (Configuration Example 5), wherein the first coil and the second coil are coils into which a resonance coil is divided.

### (Configuration Example 7)

The power supply device according to any one of (Configuration Example 1) to (Configuration Example 6), wherein the first coil includes a first core and a first winding wound on the first core, and
wherein the second coil includes a second core and a second winding wound on the second core.

While preferred embodiments of the invention have been described and illustrated above, it should be understood that these are exemplary examples of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1, 101, 201, 301 Power supply device
11, 211, 311 Housing
31 Input terminal
32 Output terminal
41 Transformer
51, 61, 151, 251 Substrate
53, 63, 153, 253 Pedestal
A1, A2, A3, A13, A101, A102, A103 Face
C1, C2, C1a, C2a, C11, C12, C21, C22, C31, C32, C41, C42, C51, C52, C61, C62, C63 Coil
D1, D2, D11 Direction
E1, E2, E11, E12, E21, E22, E31, E32 Mounting part
F1, F2, F11, F101 Fan
J1, J1a, J2, J2a, J11, J12, J21, J22, J31, J32, J41, J42, J51, J52, J61, J62, J63 Core
K1, K1a, K2, K2a, K11, K12, K21, K22, K31, K32, K41, K42, K51, K52, K61, K62, K63 Winding
R1 Region

What is claimed is:

1. A power supply device comprising a first coil, a second coil, a substrate, an air blower, and a housing that houses the first coil, the second coil, the substrate, and the air blower,
wherein the first coil and the second coil are connected in series or in parallel, and
wherein at least parts of the first coil and the second coil are included in a field of view at a viewpoint at which the first coil and the second coil are seen in the same direction as an air blowing direction of the air blower.

2. The power supply device according to claim 1, wherein a second distance of the second coil disposed on the substrate from the substrate is larger than a first distance of the first coil disposed on the substrate from the substrate, and
wherein the second coil is disposed at a position closer to the air blower than the first coil, and the air blowing direction in the air blower is a direction in which air is blown outward from the inside of the housing.

3. The power supply device according to claim 1, wherein a second distance of the second coil disposed on the substrate from the substrate is larger than a first distance of the first coil disposed on the substrate from the substrate, and
wherein the second coil is disposed at a position farther from the air blower than the first coil, and the air blowing direction in the air blower is a direction in which air is blown inward from the outside of the housing.

4. The power supply device according to claim 1, further comprising a pedestal which is disposed on the substrate and on which the first coil and the second coil are mounted.

5. The power supply device according to claim 2, further comprising a pedestal which is disposed on the substrate and on which the first coil and the second coil are mounted.

6. The power supply device according to claim 3, further comprising a pedestal which is disposed on the substrate and on which the first coil and the second coil are mounted.

7. The power supply device according to claim 4, wherein the pedestal includes a first mounting part on which the first coil is mounted and a second mounting part on which the second coil is mounted, and
wherein a fourth distance of the second mounting part from the substrate is larger than a third distance of the first mounting part from the substrate.

8. The power supply device according to claim 5, wherein the pedestal includes a first mounting part on which the first coil is mounted and a second mounting part on which the second coil is mounted, and
wherein a fourth distance of the second mounting part from the substrate is larger than a third distance of the first mounting part from the substrate.

9. The power supply device according to claim 6, wherein the pedestal includes a first mounting part on which the first coil is mounted and a second mounting part on which the second coil is mounted, and
wherein a fourth distance of the second mounting part from the substrate is larger than a third distance of the first mounting part from the substrate.

10. The power supply device according to claim 1, wherein the first coil and the second coil are coils into which a resonance coil is divided.

11. The power supply device according to claim 2, wherein the first coil and the second coil are coils into which a resonance coil is divided.

12. The power supply device according to claim 3, wherein the first coil and the second coil are coils into which a resonance coil is divided.

13. The power supply device according to claim 1, wherein the first coil includes a first core and a first winding wound on the first core, and
wherein the second coil includes a second core and a second winding wound on the second core.

14. The power supply device according to claim 2, wherein the first coil includes a first core and a first winding wound on the first core, and
wherein the second coil includes a second core and a second winding wound on the second core.

15. The power supply device according to claim 3, wherein the first coil includes a first core and a first winding wound on the first core, and
wherein the second coil includes a second core and a second winding wound on the second core.
